(19) United States
(12) Patent Application Publication
(10) Pub. No.: US 2025/0258223 A1
(43) Pub. Date: Aug. 14, 2025

(54) DYNAMIC SELECTION METHOD, SYSTEM AND DEVICE FOR DATA REGION APPLIED TO INTEGRATED CIRCUIT DEVICE AND COMPUTER-READABLE STORAGE MEDIUM

(71) Applicant: PRIMARIUS TECHNOLOGIES CO., LTD., Shanghai (CN)

(72) Inventors: Hancheng LIANG, Shanghai (CN); Kai SHI, Shanghai (CN); Zhihong LIU, Shanghai (CN)

(21) Appl. No.: 18/862,785

(22) PCT Filed: Dec. 28, 2022
(86) PCT No.: PCT/CN2022/142570

§ 371 Date: Nov. 4, 2024

(30) Foreign Application Priority Data
May 6, 2022 (CN) 202210485167.6

(51) Int. Cl. G01R 31/3183; G01R 31/317; G06F 30/32

(52) U.S. Cl. CPC G01R 31/318357; G01R 31/31704; G06F 30/32

(57) ABSTRACT

The present application provides a dynamic selection method, system and device for a data region applied to an integrated circuit device, and a computer-readable storage medium. Through the technical solutions provided by the present application, the dynamic selection for the data region can be achieved, the strict dependence on an original dataset in the data region selection process is removed, the complexity of data region selection for different integrated circuit devices is simplified, and the universality and reusability of data region selection are improved. The application range is wide, and the popularization value is achieved.

### TECHNICAL FIELD

The present invention relates to the technical field of integrated circuit testing, and more particularly, discloses a dynamic selection method, system and device for a data region applied to an integrated circuit device, and a computer-readable storage medium.

### BACKGROUND ART

With the continuous development of science and technology levels, the analysis for the work of devices through the establishment of models in the field of integrated circuits has become one of the more common technical means, while the accurate division and selection for behavior regions reflected by device data is a key link in a process strategy for parameter extraction from an integrated circuit device model.

In the prior art, due to the differences between integrated circuit devices, including differences between factors such as measurement conditions, bias conditions, data scanning ranges, and single scanning step sizes of the integrated circuit devices, it is difficult to achieve the automation and generalization in the model parameter extraction process.

### SUMMARY OF THE INVENTION

In order to solve the above-mentioned problems existing in the prior art, the present invention provides a dynamic selection method, system and device for a data region applied to an integrated circuit device, and a computer-readable storage medium.

A first aspect of the present application provides a dynamic selection method for a data region applied to an integrated circuit device. The dynamic selection method may specifically include: acquiring a test dataset and/or simulation dataset corresponding to the integrated circuit device: acquiring a plurality of bias condition variables associated with the integrated circuit device according to a user instruction, the bias condition variables being associated with a data item to be tested and/or a data item to be simulated of the integrated circuit device:

acquiring bias conditions corresponding to the bias condition variables according to the user instruction:

generating a customized selection model associated with the data item to be tested and/or the data item to be simulated according to the bias condition variables and the bias conditions:

selecting a corresponding dynamic test dataset from the test dataset according to the customized selection model; and/or

selecting a corresponding dynamic simulation dataset from the simulation dataset according to the customized selection model; and

performing a test operation according to the dynamic test dataset and/or performing a simulation operation according to the dynamic simulation dataset for the integrated circuit device.

In a possible implementation of the first aspect, the bias condition variables include a plurality of first feature points of the data item to be tested: and/or

a plurality of second feature points of the data item to be simulated.

In a possible implementation of the first aspect, in the case that the data item to be tested includes voltages at a plurality of first test points in an integrated circuit associated with the integrated circuit device, the first feature points may include:

a maximum voltage value of the first test point, a minimum voltage value of the first test point, a zero voltage value of the first test point, a saturation voltage value of the first test point, and a valve voltage value of the first test point.

In a possible implementation of the first aspect, in the case that the data item to be simulated includes voltages at a plurality of second test points in the integrated circuit associated with the integrated circuit device, the second feature points may include:

a maximum voltage value of the second test point, a minimum voltage value of the second test point, a zero voltage value of the second test point, a saturation voltage value of the second test point, and a valve voltage value of the second test point.

In a possible implementation of the first aspect, the bias conditions corresponding to the bias condition variables are determined according to the plurality of selected first feature points and/or the plurality of selected second feature points:

The bias conditions include a data interval formed by the plurality of selected first feature points and/or second feature points.

In a possible implementation of the first aspect, the user instructions include manual instructions and machine instructions:

the dynamic selection method for the data region further includes:

storing the bias condition variables corresponding to the data item to be tested and/or the data item to be simulated:

acquiring historical bias condition variables corresponding to the data item to be tested and/or the data item to be simulated in the case that the user instructions include at least one machine instruction; and

acquiring at least one bias condition variable corresponding to the machine instructions through machine learning according to the historical bias condition variables.

In a possible implementation of the first aspect, the dynamic test dataset changes dynamically according to changes in the test dataset; and/or

the dynamic simulation dataset changes dynamically according to changes in the simulation dataset.

A second aspect of the present application provides a dynamic selection system for a data region applied to an integrated circuit device, which is applied to the dynamic selection method for the data region applied to the integrated circuit device according to the first aspect. The dynamic selection system includes:

an acquisition unit, configured to acquire a test dataset and/or simulation dataset corresponding to the integrated circuit device;

a first setting unit, configured to acquire a plurality of bias condition variables associated with the integrated circuit device according to a user instruction, the bias condition variables being associated with a data item to be tested and/or a data item to be simulated of the integrated circuit device:

a second setting unit, configured to acquire bias conditions corresponding to the bias condition variables according to the user instruction;

a generation unit, configured to generate a customized selection model associated with the data item to be tested and/or the data item to be simulated according to the bias condition variables and the bias conditions:

a selection unit, configured to select a corresponding dynamic test dataset from the test dataset according to the customized selection model; and/or

select a corresponding dynamic simulation dataset from the simulation dataset according to the customized selection model: and

a processing unit, configured to perform a test operation according to the dynamic test dataset and/or perform a simulation operation according to the dynamic simulation dataset for the integrated circuit device.

A third aspect of the present application provides a dynamic selection device for a data region applied to an integrated circuit device. The dynamic selection device may include:

a memory, configured to store a computer program therein; and

a processor, configured to implement the dynamic selection method for the data region applied to the integrated circuit device according to the first aspect while executing the computer program.

A fourth aspect of the present application provides a computer-readable storage medium. The computer-readable storage medium is configured to store a computer program therein, which, when being executed by a processor, implements the dynamic selection method for the data region applied to the integrated circuit device according to the first aspect.

Compared with the prior art, the present application has the following technical effects. Through the technical solutions provided by the present application, the dynamic selection for the data region can be achieved, the strict dependence on an original dataset in the data region selection process is removed, the complexity of data region selection for different integrated circuit devices is simplified, and the universality and reusability of data region selection are improved. The application range is wide, and the popularization value is achieved.

### BRIEF DESCRIPTION OF THE DRAWINGS

After reading the detailed description of the non-restrictive embodiments with reference to the following accompanying drawings, other features, objects and advantages of the present application will become more apparent:

FIG. 1 shows a schematic flowchart of a dynamic selection method for a data region applied to an integrated circuit device according to an embodiment of the present application:

FIG. 2 shows a schematic diagram of a part of a user interface for the selection of bias condition variables according to an embodiment of the present application:

FIG. 3 shows a schematic flowchart of a dynamic selection method for a data region based on a machine instruction according to an embodiment of the present application:

FIG. 4 shows a schematic structural diagram of a dynamic selection system for a data region applied to an integrated circuit device according to an embodiment of the present application:

FIG. 5 shows a schematic structural diagram of a dynamic selection device for a data region applied to an integrated circuit device according to an embodiment of the present application: and

FIG. 6 shows a schematic structural diagram of a computer-readable storage medium according to an embodiment of the present application.

### DETAILED DESCRIPTION OF THE INVENTION

The present application will be further described below in conjunction with the specific embodiments. The following embodiments will help a person skilled in the art to further understand the present application, but do not limit the present application in any form. It should be pointed out that for a person of ordinary skill in the art, without departing from the concept of the present application, several changes and improvements can be made. These all fall within the protection scope of the present application.

The term “including” and its variants used herein represent open-ended inclusion, i.e., “including but not limited to”. Unless otherwise stated, the term “or” means “and/or”. The term “based on” represents “at least partially based on”. The terms “one exemplary embodiment” and “one embodiment” represent “at least one exemplary embodiment”. The terms “another embodiment” represent “at least one additional embodiment”. The terms “first”, “second”, etc., may refer to different or identical objects. Other explicit and implicit definitions may also be included below.

In view of the problems existing in the prior art that the automation and generalization are hardly achieved in a model parameter extraction process, the present application provides a dynamic selection method, system and device for a data region applied to an integrated circuit device, and a computer-readable storage medium. Through the technical solutions provided by the present application, the strict dependence on an original dataset in the data region selection process can be removed, the complexity of data region selection for different integrated circuit devices is simplified, and the universality and reusability of data region selection are improved. The technical solutions provided by the present application are interpreted and described in conjunction with embodiments.

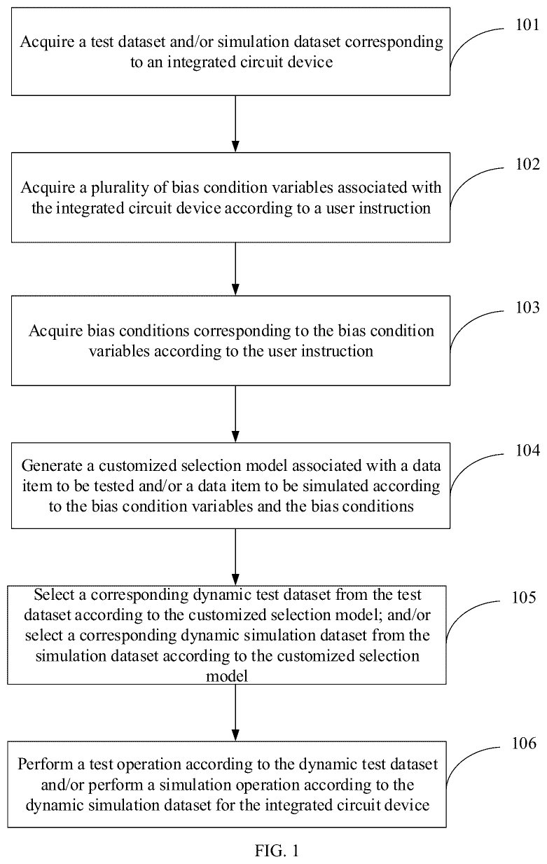

In some embodiments of the present application, FIG. 1 shows a schematic flowchart of a dynamic selection method for a data region applied to an integrated circuit device.

As shown in FIG. 1, the dynamic selection method for the data region applied to the integrated circuit device may specifically include the following steps.

Step 101: acquire a test dataset and/or simulation dataset corresponding to the integrated circuit device.

Step 102: acquire a plurality of bias condition variables associated with the integrated circuit device according to a user instruction. The bias condition variables are associated with a data item to be tested and/or a data item to be simulated of the integrated circuit device.

Step 103: acquire bias conditions corresponding to the bias condition variables according to a user instruction. The above step 102 and step 103 may be performed synchronously in the actual application process. For example, a setting interface for condition selection may be provided for a user. The setting interface may include a drop-down menu option for a plurality of bias condition variables. The user may enter the required bias condition variables and related bias conditions by himself or herself according to the needs.

Step 104: generate a customized selection model associated with the data item to be tested and/or the data item to be simulated according to the bias condition variables and the bias conditions.

Step 105: select a corresponding dynamic test dataset from the test dataset according to the customized selection model: and/or select a corresponding dynamic simulation dataset from the simulation dataset according to the customized selection model.

Step 106: perform a test operation according to the dynamic test dataset and/or perform a simulation operation according to the dynamic simulation dataset for the integrated circuit device. It may be understood that through the steps 101 to 106 above, the dynamic selection for the data region can be achieved. The specific implementation of the steps 101 to 106 above will be further interpreted and described below.

In some embodiments of the present application, the bias condition variables include a plurality of first feature points of the data item to be tested: and/or a plurality of second feature points of the data item to be simulated.

The following will specifically describe and interpret the selection for “anchor points”, i.e., the first and second feature points, by means of the specific embodiments: in some specific embodiments of the present application, the data item to be tested or the data item to be simulated may be set as voltage parameters, then in the case that the data item to be tested includes voltage at a plurality of first test points in an integrated circuit associated with the integrated circuit device, the first feature points may include a maximum voltage value of the first test point, a minimum voltage value of the first test point, a zero voltage value of the first test point, a saturation voltage value of the first test point and a valve voltage value of the first test point. In the case that the data item to be simulated includes voltage at a plurality of second test points in the integrated circuit associated with the integrated circuit device, the second feature points may include: a maximum voltage value of the second test point, a minimum voltage value of the second test point, a zero voltage value of the second test point, a saturation voltage value of the second test point, and a valve voltage value of the second test point.

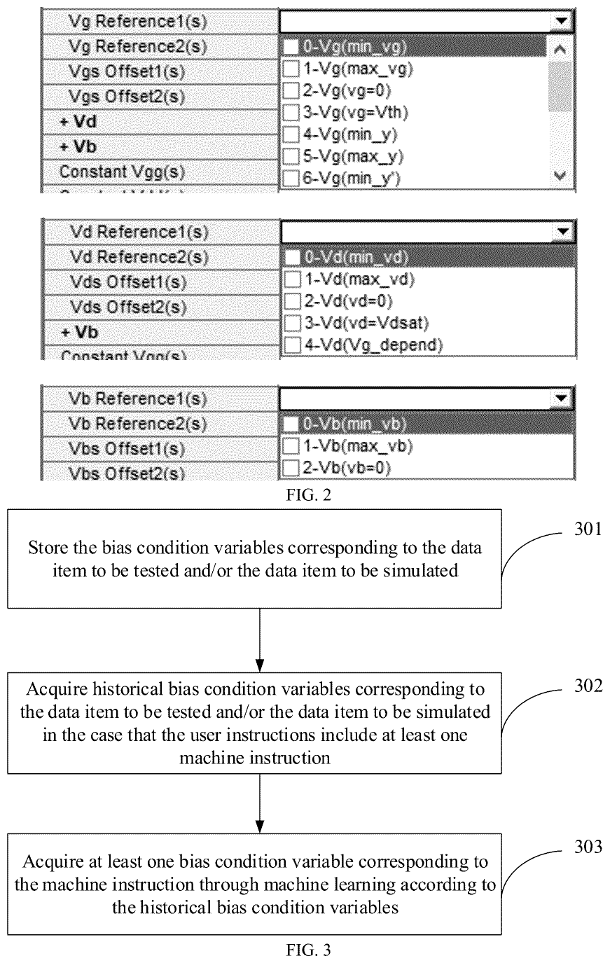

Specifically, FIG. 2 shows a schematic diagram of a user interface for the selection of bias condition variables. It can be seen that in the process of setting bias condition variables for voltage parameters of an integrated circuit device, Vg Reference, Vd Reference, and Vb Reference may be selected as “anchor points”, respectively. As shown in FIG. 2, specific variable information of the anchor points may be selected in the user interface by means of a drop-down menu.

Further, in the above embodiment, the bias conditions corresponding to the bias condition variables may be determined according to the plurality of selected first feature points and/or the plurality of selected second feature points. For example, the bias conditions may include a data interval formed by the plurality of selected first feature points and/or second feature points.

In some embodiments of the present application, it may be understood that the user instructions may include both manual instructions and machine instructions. In the case that the user instructions include the machine instructions, it is indicated that the dynamic selection method for the data region provided by the present application may be applied to an automatic or semi-automatic model parameter extraction process strategy.

Specifically, FIG. 3 shows a schematic flowchart of a dynamic selection method for a data region based on a machine instruction. As shown in FIG. 3, the method may specifically includes the following steps.

Step 301: store the bias condition variables corresponding to the data item to be tested and/or the data item to be simulated.

Step 302: acquire historical bias condition variables corresponding to the data item to be tested and/or the data item to be simulated in the case that the user instructions include at least one machine instruction.

Step 303: acquire at least one bias condition variable corresponding to the machine instructions through machine learning according to the historical bias condition variables.

It may be understood that in the process of executing the automatic or semi-automatic model parameter extraction process strategy, based on the data item to be tested and/or the data item to be simulated, the current bias condition variables of this data item may be confirmed by means of machine learning and other methods according to the characteristics of the data itself and the historical bias condition variables.

In some embodiments of the present application, the dynamic test dataset may change dynamically according to changes in the test dataset: and/or the dynamic simulation dataset may change dynamically according to changes in the simulation dataset.

In some embodiments of the present application, the above-mentioned dynamic selection method for the data region applied to the integrated circuit device may be applied to current BSIMProplus™ and SDEP products. BSIMProplus™ is the industry's most leading SPICE modeling platform for semiconductor devices, having been the leader in the global SPICE modeling market and technology for over two decades, and is adopted by over 100 leading integrated circuit manufacturing and design companies worldwide as a standard SPICE modeling tool. Based on its integrated parallel SPICE engine, BSIMProplus™ provides the industry's most powerful fully integrated SPICE modeling platform, which may be used to perform SPICE modeling on various device characteristics of various semiconductor devices from low frequency to high frequency, including electrical characteristic testing, automatic parameter extraction and optimization of device models, model validation, etc. The technical solutions provided in the present application can achieve seamless docking with the above-mentioned existing platform.

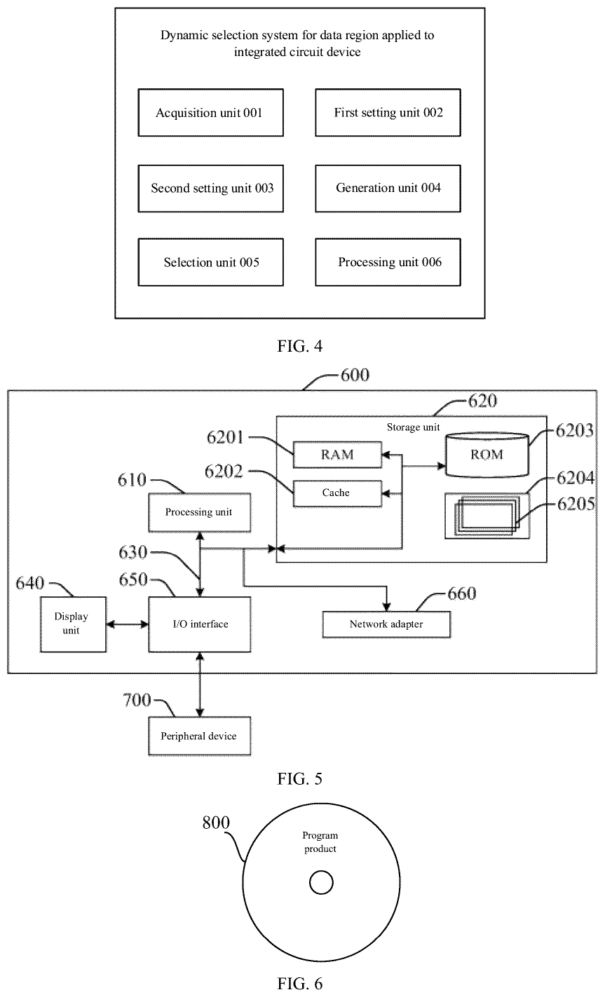

In some embodiments of the present application, FIG. 4 shows a dynamic selection system for a data region applied to an integrated circuit device, which is applied to the dynamic selection method for the data region applied to the integrated circuit device provided in the above-mentioned embodiment. The system may specifically include:

an acquisition unit 001, configured to acquire a test dataset and/or simulation dataset corresponding to the integrated circuit device:

a first setting unit 002, configured to acquire a plurality of bias condition variables associated with the integrated circuit device according to a user instruction, the bias condition variables being associated with a data item to be tested and/or a data item to be simulated of the integrated circuit device:

a second setting unit 003, configured to acquire bias conditions corresponding to the bias condition variables according to a user instruction:

a generation unit 004, configured to generate a customized selection model associated with the data item to be tested and/or the data item to be simulated according to the bias condition variables and the bias conditions:

a selection unit 005, configured to select a corresponding dynamic test dataset from the test dataset according to the customized selection model: and/or select a corresponding dynamic simulation dataset from the simulation dataset according to the customized selection model; and

a processing unit 006, configured to perform a test operation according to the dynamic test dataset and/or perform a simulation operation according to the dynamic simulation dataset for the integrated circuit device.

It may be understood that, in the above embodiment, the functions performed by the acquisition unit 001 to the processing unit 006 are consistent with the actions performed by the steps 101 to 106 in the above-mentioned embodiment, and will not be repeated herein.

In some embodiments of the present application, a dynamic selection device for a data region applied to an integrated circuit device is also provided. The device may include:

a memory, configured to store a computer program therein: and

a processor, configured to perform the steps for implementing the dynamic selection method for a data region applied to an integrated circuit device described in the technical solution of the present application while executing the computer program.

It may be understood that aspects of the technical solutions of the present application may be implemented as a system, a method or a program product. Therefore, all aspects of the technical solutions of the present application may be specifically implemented in the following forms, namely, a complete hardware embodiment, a complete software embodiment (including firmware, microcodes, etc.), or a combination of hardware and software, which may be collectively referred to herein as a “circuit”, “module” or “platform”.

FIG. 5 shows a schematic structural diagram of a dynamic selection device for a data region applied to an integrated circuit device according to some embodiments of the present application. An electronic device 600 implemented according to the implementation of the present embodiment is described in detail with reference to FIG. 5 below. The electronic device 600 shown in FIG. 5 is only an example and should not impose any limitation on the functionality and scope of use in any embodiment of the technical solutions in the present application.

As shown in FIG. 5, the electronic device 600 is expressed in the form of a general-purpose computing device. The assembly of the electronic device 600 may include, but is not limited to: at least one processing unit 610, at least one storage unit 620, a bus 630 configured to connect different platform components (including the storage unit 620 and the processing unit 610), a display unit 640, etc.

The storage unit has program codes stored therein. The program codes may be executed by the processing unit 610, so that the processing unit 610 executes the implementation steps in the present embodiment described in the dynamic selection method for a data region applied to an integrated circuit device described in the present embodiment. For example, the processing unit 610 may perform the steps shown in FIGS. 1 through 4.

The storage unit 620 may include a readable medium in the form of a volatile storage unit, such as a random access memory (RAM) 6201 and/or a cache memory 6202, and may further include a read-only memory (ROM) 6203.

The storage unit 620 may further include a program/utility tool 6204 having a set of (at least one) program modules 6205. Such program module 6205 includes, but is not limited to, an operating system, one or more application programs, other program modules, and program data. Each or any combination of these examples may include an implementation of a network environment.

The bus 630 may represent one or more of several types of bus structures, including a storage unit bus or a storage unit controller, a peripheral bus, a graphics acceleration port, a processing unit, or a local bus using any of bus structures.

The electronic device 600 may also communicate with one or more external devices 700 (for example, a keyboard, a pointing device, and a Bluetooth device), and may also communicate with one or more devices enabling a user to interact with the electronic device 600, and/or any device (such as a router and a modem) enabling the electronic device to communicate with one or more other computing devices. Such communication may be performed through an input/output (I/O) interface 650. Moreover, the electronic device 600 may also communicate with one or more networks (for example, a local area network (LAN), a wide area network (WAN) and/or a public network such as the Internet) through a network adapter 660. The network adapter 660 may communicate with other modules of the electronic device 600 through the bus 630. It should be understood that although not shown in FIG. 5, other hardware and/or software modules may be used in conjunction with the electronic device 600, and may include but not limited to a microcode, a device driver, a redundant processing unit, an external disk drive array, an RAID system, a magnetic tape drive, a data backup storage platform, etc.

In some embodiments of the present application, a computer-readable storage medium is further provided. The computer-readable storage medium is configured to store a computer program therein, which, when being executed by a processor, implements the related steps of the dynamic selection method for the data region applied to the integrated circuit device according to the above-mentioned embodiment.

Although the present embodiment does not exhaustively enumerate other specific embodiments, in some possible embodiments, the aspects described in the technical solutions of the present application may also be implemented in the form of a program product, which includes program codes. When the program product runs on a terminal device, the program codes are configured to enable the terminal device to perform the steps in various embodiments of the technical solutions of the present application described in the dynamic selection method for a data region applied to an integrated circuit device in the technical solution of the present application.

FIG. 6 shows a schematic structural diagram of a computer-readable storage medium according to some embodiments of the present application. As shown in FIG. 6, a program product 800 configured to implement the above method according to the embodiment of the technical solution in the present application is described, which may adopt a portable compact disk read-only memory (CD-ROM) and include program codes, and may run on a terminal device, such as a personal computer. Of course, the program product produced according to the present embodiment is not limited thereto. In the technical solution of the present application, the readable storage medium may be any tangible medium including or storing a program, which may be used by an instruction execution system, apparatus or device or used in combination therewith.

The program product may employ any combination of one or more readable media. The readable medium may be a readable signal medium or a readable storage medium. The readable storage medium may include, for example, but not limited to, electrical, magnetic, optical, electromagnetic, infrared, or semiconductor systems, apparatuses or devices, or any combination thereof. More specific examples (non-exhaustive list) of the readable storage media include: an electrical connection with one or more wires, a portable disk, a hard disk, a random access memory (RAM), a read-only memory (ROM), an erasable programmable read-only memory (EPROM or flash), an optical fiber, a portable compact disk read-only memory (CD-ROM), an optical storage device, a magnetic storage device, or any suitable combination of the above.

The computer-readable storage medium may include a data signal included in a baseband or propagated as part of a carrier which carries readable program codes. This propagated data signal may take many forms, including but not limited to, an electromagnetic signal, an optical signal, or any suitable combination of the above. The readable storage medium may also be any readable medium other than the readable storage medium. This readable medium may send, propagate, or transmit programs used by or used in combination with an instruction execution system, apparatus or device. The program codes contained in the readable storage medium may be transmitted using any appropriate medium, including but not limited to: a wireless mode, a wire, an optical cable, an RF, etc., or any suitable combination thereof.

The program codes for performing the operations of the technical solutions of the present application may be compiled in any combination of one or more programming languages, wherein the programming languages include object-oriented programming languages, such as Java and C++, as well as conventional procedural programming languages, such as the “C” language or similar programming languages. The program codes may be executed entirely on a user's computing device, partly on a user device, as a stand-alone software package, partly on the user's computing device and partly on a remote computing device, or entirely on a remote computing device or a server. In a case of the remote computing device, the remote computing device may be connected to a user's computing device through any type of network (including a local area network or wide area network), or may be connected to an external computing device (e.g., using an Internet service provider via the Internet).

In summary, through the technical solutions provided by the present application, the dynamic selection for the data region can be achieved, the strict dependence on an original dataset in the data region selection process is removed, the complexity of data region selection for different integrated circuit devices is simplified, and the universality and reusability of data region selection are improved. The application range is wide, and the popularization value is achieved.

The above description is only a description of the preferred embodiments of the technical solutions of the present application, and does not limit the scope of the technical solutions of the present application, and any changes and modifications made by a person of ordinary skill in the field of the technical solutions of the present application according to the above disclosure should fall within the protection scope of the claims.

1. A dynamic selection method for a data region applied to an integrated circuit device, comprising:
acquiring a test dataset and/or simulation dataset corresponding to the integrated circuit device;
acquiring a plurality of bias condition variables associated with the integrated circuit device according to a user instruction, the bias condition variables being associated with a data item to be tested and/or a data item to be simulated of the integrated circuit device;
acquiring bias conditions corresponding to the bias condition variables according to a user instruction;
generating a customized selection model associated with the data item to be tested and/or the data item to be simulated according to the bias condition variables and the bias conditions;
selecting a corresponding dynamic test dataset from the test dataset according to the customized selection model; and/or
selecting a corresponding dynamic simulation dataset from the simulation dataset according to the customized selection model; and
performing a test operation according to the dynamic test dataset and/or perform a simulation operation according to the dynamic simulation dataset for the integrated circuit device.

2. The dynamic selection method for the data region applied to the integrated circuit device according to claim 1, wherein the bias condition variables comprise a plurality of first feature points of the data item to be tested; and/or a plurality of second feature points of the data item to be simulated.

3. The dynamic selection method for the data region applied to the integrated circuit device according to claim 2, wherein in the case that the data item to be tested comprises voltages at a plurality of first test points in an integrated circuit associated with the integrated circuit device, the first feature points comprise:
a maximum voltage value of the first test point, a minimum voltage value of the first test point, a zero voltage value of the first test point, a saturation voltage value of the first test point, and a valve voltage value of the first test point.

4. The dynamic selection method for the data region applied to the integrated circuit device according to claim 2, wherein in the case that the data item to be simulated comprises voltages at a plurality of second test points in the integrated circuit associated with the integrated circuit device, the second feature points comprise:
a maximum voltage value of the second test point, a minimum voltage value of the second test point, a zero voltage value of the second test point, a saturation voltage value of the second test point, and a valve voltage value of the second test point.

5. The dynamic selection method for the data region applied to the integrated circuit device according to claim 2, wherein the bias conditions corresponding to the bias condition variables are determined according to the plurality of selected first feature points and/or the plurality of selected second feature points; and
the bias conditions comprise a data interval formed by the plurality of selected first feature points and/or second feature points.

6. The dynamic selection method for the data region applied to the integrated circuit device according to claim 1, wherein the user instructions comprise manual instructions and machine instructions; and
the dynamic selection method for the data region further comprises:
storing the bias condition variables corresponding to the data item to be tested and/or the data item to be simulated;
acquiring historical bias condition variables corresponding to the data item to be tested and/or the data item to be simulated in the case that the user instructions comprise at least one machine instruction; and
acquiring at least one bias condition variable corresponding to the machine instructions through machine learning according to the historical bias condition variables.

7. The dynamic selection method for the data region applied to the integrated circuit device according to claim 1, wherein the dynamic test dataset changes dynamically according to changes in the test dataset; and/or the dynamic simulation dataset changes dynamically according to changes in the simulation dataset.

8. A dynamic selection system for a data region applied to an integrated circuit device, which is applied to the dynamic selection method for the data region applied to the integrated circuit device according to claim 1, the system comprising:
an acquisition unit, configured to acquire a test dataset and/or simulation dataset corresponding to the integrated circuit device;
a first setting unit, configured to acquire a plurality of bias condition variables associated with the integrated circuit device according to a user instruction, the bias condition variables being associated with a data item to be tested and/or a data item to be simulated of the integrated circuit device;
a second setting unit, configured to acquire bias conditions corresponding to the bias condition variables according to the user instruction;
a generation unit, configured to generate a customized selection model associated with the data item to be tested and/or the data item to be simulated according to the bias condition variables and the bias conditions;
a selection unit, configured to select a corresponding dynamic test dataset from the test dataset according to the customized selection model; and/or
select a corresponding dynamic simulation dataset from the simulation dataset according to the customized selection model; and
a processing unit, configured to perform a test operation according to the dynamic test dataset and/or perform a simulation operation according to the dynamic simulation dataset for the integrated circuit device.

9. A dynamic selection device for a data region applied to an integrated circuit device, comprising:
a memory, configured to store a computer program therein; and
a processor, configured to implement the dynamic selection method for the data region applied to the integrated circuit device according to claim 1 while executing the computer program.

10. A computer-readable storage medium, having a computer program stored therein, the computer program being executed by a processor to implement the dynamic selection method for the data region applied to the integrated circuit device according to any one of claim 1.
